(19) United States
(12) Patent Application Publication
(10) Pub. No.: US 2023/0178673 A1
(43) Pub. Date: Jun. 8, 2023

(54) Design and Fabrication Method of Hetero-structured Solar Cell Using Non-Crystalline a-Si/poly-Si

(71) Applicants: Samson Mil'shtein, Chelmsford, MA (US); Dhawal Narain Asthana, Lowell, MA (US)

(72) Inventors: Samson Mil'shtein, Chelmsford, MA (US); Dhawal Narain Asthana, Lowell, MA (US)

(21) Appl. No.: 17/535,813

(22) Filed: Nov. 26, 2021

(51) Int. Cl. H01L 31/0747

(52) U.S. Cl. CPC H01L 31/0747

(57) ABSTRACT

History of commercial production of solar cells made from polysilicon material (E_{ff} =15 -17%) and from amorphous silicon (Eff = 9 - 12%) has accumulated understanding of deficiencies and limitations of these solar cells. The present design combines following technical requirements: a) ability to harvest energy from widest part of sun spectrum; b) offer highest values of absorption coefficient for photons of the selected part of sun spectrum; c) ensure highest efficiency of conversion of incident photons into electron-hole pairs or photocarriers while ensuring lowest recombination rate; d) The simplicity of fabrication and low cost of mass production.

### INTRODUCTION

The properties of both materials, a-Si and poly-Si are intensely studied experimentally through years [1-10]. With offering simplicity for fabricating poly-Si wafers and ribbons on one hand, these materials suffer from low absorption coefficient. On the other hand, thin film poly-Si quickly heats up under sun irrigation by high energy photons. As a result, these solar cells are losing 1% efficiency with every 10° C. increase of the temperature. Very simple technology of making a-Si layers produces materials with high density of dangling bonds, i.e., very high recombination rate of photocarriers generated by sunlight. Hydrogenation of a-Si films significantly improves performance of these solar cells. However, thin film a-Si solar cells are effectively blind to part of the sun spectrum with photon energy less than 1.8 eV. In the design of heterostructure solar cells combining a-Si with poly-Si we were motivated to avoid mentioned above deficiencies of these materials.

With offering simplicity for fabricating poly-Si wafers and ribbons on one hand, these materials suffer from low absorption coefficient. On the other hand, thin film poly-Si quickly heats up under sun irrigation by high energy photons. As a result, these solar cells are losing 1% efficiency with every 10° C. increase of the temperature. Very simple technology of making a-Si layers produces materials with high density of dangling bonds, i.e., very high recombination rate of photocarriers generated by sunlight. Hydrogenation of a-Si films significantly improves performance of these solar cells. However, thin film a-Si solar cells are effectively blind to part of the sun spectrum with photon energy less than 1.8 eV. In the design of heterostructure solar cells combining a-Si with poly-Si we were motivated to avoid mentioned above deficiencies of these materials.

### DESCRIPTION OF INVENTION

In design of our solar cell, a thin highly doped layer of a-Si is used. However, high density of dangling bonds, about 10²⁰cm⁻³, in a-Si [5-6] causes high recombination rate of photocarriers. To reduce this high recombination rate commercial layers of a-Si are subjected to hydrogenation during processing. It is known [7] that plasma hydrogenation carries high processing costs. In the underlying a-Si p-type 0.1 µm thick layer, the doping gets to a high level ranging from 10¹⁷ to 10⁹cm⁻³ to suppress activities of dangling bonds and reduce recombination rate of photocarriers.

The heterojunction is completed by a 100 µm thick base of poly-Si under the a-Si layers. As per the illustrations provided in FIG. 1 and FIG. 2, high doping implies impurity concentration falling in the range 10¹⁸ - 10¹⁹/cm³ dopant/impurity atoms per cubic centimeter in the semiconductor material. Medium level doping implies impurity concentration falling in the range 10¹³ - 10¹⁷ /cm³ dopant/impurity atoms per cubic centimeter in the semiconductor material. FIG. 1 illustrates an embodiment of the solar cell structure in which the layer of a-Si at the top is doped with acceptor type atoms (p-type impurities) and the layer made of poly-Si at the bottom is doped with donor type atoms (n-type impurities). On the other hand, FIG. 2 illustrates another embodiment of the solar cell design in which the layer made of a-Si at the top is doped with donor type atoms (n-type impurities) and the layer made of poly-Si at the bottom is doped with acceptor type atoms (p-type impurities).

The complete structure of the solar cell was studied using finite element analysis to find its response to AM1.5 solar spectrum. The intensity of this solar spectrum was assumed to be 1000 W/m². The output current vs voltage characteristics is presented in FIG. 3 in which the open circuit voltage and short circuit current are 0.674 V and 36.45 mA/cm² respectively. At 85.2%, since the value of fill factor is also high, optimized performance of the solar cell with decrease in losses due to recombination is also indicated in the shape of this output characteristic curve, which is more rectangular and indicates best performance.

The other parameters of the solar that resulted from the study arc- a) Maximum Power (Pm)= 20.94 mW/cm², b) Voltage between the electrodes during maximum power production (Vₘ)= 0.6 V, c) Output current from the solar cell during maximum power production (Iₘ)=34.9 mA/cm² and d) Overall efficiency of the solar cell (Eff) =20.5%.

Most important is the fact, that our design does not carry crystalline materials and therefore is free of complicated consideration about lattice match between adjacent layers. The main specificity of the proposed design is suppression of recombination rates in both, amorphous and polycrystalline layers the structure. Instead of using hydrogenation of dangling bonds, which is costly technology, we propose to use diffusion of impurities in thin amorphous layers and ion implantation of polysilicon.

The production of epi-all are layers of our solar cell could be done by Liquid Phase Epitaxy (LPE). LPE is known to be the simplest and least costly epitaxy. There is no preferential etching direction of amorphous silicon surface. Typical donors and acceptors used in production of commercial diodes can be used in a-Si/poly-Si solar cell.

Configuration of a-Si/poly-Si solar cell final structure can be produced with donor doping at the amorphous, top layer, and acceptor doping of the poly- silicon, or vice versa with acceptor doping of the amorphous, top layer, and donor doping of the poly- silicon layer.

The manufacturing of a-Si/poly-Si solar cell could use simple liquid epitaxy or any of commercial production steps such as SSP (Standard Screen Printed), PERC (Passivated Emitter Rear Contact) or IBC (Interdigitated back contact solar cells)

### BRIEF DESCRIPTION OF THE DRAWINGS

The accompanied drawings have been vividly described in the description of invention. This section describes the aspects of the drawings that are relevant to the design of the proposed solar cell.

FIG. 1. is a diagrammatic representation of an embodiment of the invention in which the a-Si layer (top layer) is doped with acceptor type (p-type) impurities and the poly-Si layer at the bottom is doped with donor type (n-type) impurities.

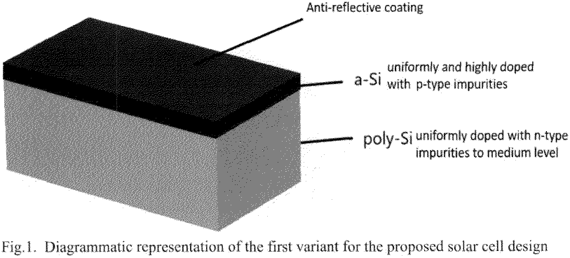

FIG. 2. is a diagrammatic representation of another embodiment of the invention in which the a-Si layer (top layer) is doped with donor type (n-type) impurities and the poly-Si layer at the bottom is doped with acceptor type (p-type) impurities.

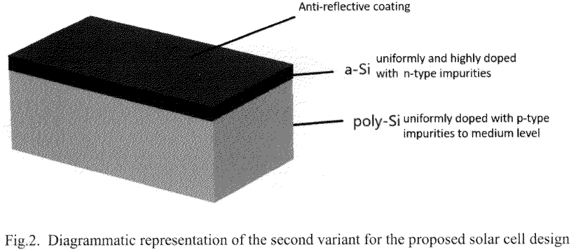

FIG. 3 depicts output current vs voltage characteristics that was realized for the proposed design by using finite element analysis method. It contains value of current density in mA/cm² plotted along y-axis and the voltage occurring between the top layer and the bottom layer of the designed solar cell along the x-axis.

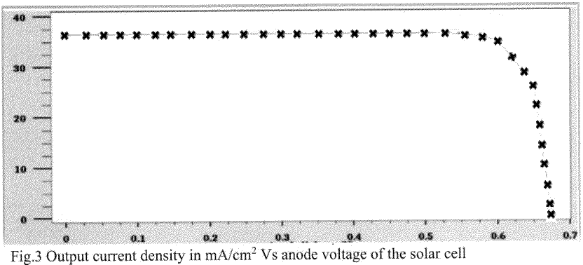

### REFERENCES

[1] Tianyu Ruan, Minghao Qu, Xianlin Qu, Xiaoning Ru, Jianqiang Wang, Yongcai He, Kun Zheng, Bo Heb Hongfeng Lin, Xixiang Xu, Yongzhe Zhang, Hui Yan,“Achieving high efficiency silicon heterojunction solar cells by applying high hydrogen content amorphous silicon as epitaxial-free buffer layers”, Thin Solid Films, Vol. 711, 138305, 2020
[2] K. Shepard, Z E. Smith, S. Aljishi, and S. Wagner , “Kinetics of the generation and annealing of deep defects and recombination centers in amorphous silicon”, Appl. Phys. Lett. 53, 16441646, 1988
[3] Wayesh Qarony, Mohammad I. Hossain, M. Khalid Hossain, M. Jalal Uddin, A. Haque, A.R. Saad, Yuen Hong Tsang, “Efficient amorphous silicon solar cells: characterization, optimization, and optical loss analysis, Results in Physics, vol. 7, pp. 4287-4293, 2017 [4] Z. Marviab, S. Xu*a, G. Foroutanb, K. Ostrikovcd and I. Levchenkoad,” Plasma-deposited hydrogenated amorphous silicon films: multiscale modelling reveals key processes” RSC Adv., Vol. 7, 19189-19196, 2017
[5] L. Sirleto, G. Coppola, M. Iodice, M. Casalino, M. Gioffre, I. Rendina, 3 - Thermo-optical switches, Editor(s): Baojun Li, Soo Jin Chua, In Woodhead Publishing Series in Electronic and Optical Materials, Optical Switches, Woodhead Publishing, pp. 61-96, 2010
[6] Aguas, H. & Ram, Sanjay & Araújo, Andreia & Gaspar, Diana & Vicente, Antonio & Filonovich, Sergej & Fortunato, Elvira & Martins, R. & Ferreira, Isabel. Silicon thin film solar cells on commercial tiles. Energy & Environmental Science. 4. 4620-4632. 10.1039/clee02303a., 2011
[7] C. Walsh “Solar cell efficiency: n-type v. p-type”, CED Greentech, 2017. Available at: https://www.cedgreentech.com/article/solar-cell-efficiency-n-type-v-p-type
[8] J. Valenzuela, S. Mil’shtein, “Design of Triple Layer Polymer Solar Cell”, Intern. Conf., Clean Technology, CTSI-08, ISBN 978-4200-8502-0, p. 124-127, (2008).
[9] B. Srinivasan, A. Solanki, S. Mil’shtein, “Design of a Solar Cell with Better Spectral Utilization Using Down-Conversion”, Intern. Conf. Phys. Semicond., ICPS-29, p, 582, 2008.
[10] J. Valenzuela, S. Milshtein,“Quantum Well Model of a Conjugated Polymer Heterostructure Solar Cell”, Microelectronics Jour. 40, p. 424-426, (2009)

### RELATED PATENTS

[1] Irie, et al. “Method for manufacturing solar cell, solar cell, and solar cell module” U.S. Pat. No. 11,177,407, 2021
[2] Che-Yao Wu “Thin film solar cell”, U.S. Pat. No. 11,177,405, 2021
[3] Daisuke Adachi “Crystalline silicon solar cell and method for producing same” U.S. Pat. No. 11,024,760, 2021

1. The high efficiency of the solar cell achieved by hetero-structural combination of two noncrystalline Silicon materials, namely, a-Si (amorphous) and poly-Si (polysilicon).

2. The 0.2 µm thick p-type amorphous Si is the top layer of the solar cell to absorb all photons with energy Eₚₕ>1.9 eV (from sun spectra.

3. The 99.1 µm thick n-type poly-Si is the base layer of hetero-structured solar cell to absorb all photons with energy 1.1 eV<Eₚₕ <1.8 eV.

4. In agreement with claim 2 the 0.2 µm thick p-type amorphous Si layer is uniformly doped by 10¹⁸cm⁻³ donor density to suppress recombination rate of electron -hole carriers generated by sun light.

5. In agreement with claim 3 the 99.1 µm thick n-type poly-Si layer is uniformly doped by donor type impurity concentration falling in the range 10¹³ - 10¹⁷ /cm³ to suppress recombination rate of electron -hole carriers generated by sun light.

6. In agreement with claims 1 and 3 the 99.1 µm thick n-type poly-Si base layer of heterostructured solar cell is produced by liquid epitaxy or grown as ribbon from silicon melt.

7. In agreement with claims 1 and 2 the 0.2 µm thick p-type amorphous Si is the top layer of the solar cell is grown on base layer by CVD epitaxy, or any of commercial fabrication methods, such as such as SSP (Standard Screen Printed), PERC (Passivated Emitter Rear Contact) or IBC (Interdigitated Back Contact) solar cells.

8. In agreement with claims 1,2,4, and 7 the 0.2 µm thick p-type amorphous Si covered by antireflection coating.

9. In agreement with claims 1 and 2 the 0.2 µm thick p-type amorphous Si is the top layer of the solar cell will prevent overheating of the base layer, thus keeping efficiency of the solar cell steady under intense solar radiation.
